(19) United States
(12) Patent Application Publication
(10) Pub. No.: US 2011/0287603 A1
(43) Pub. Date: Nov. 24, 2011

(54) METHOD FOR MANUFACTURING SILICON CARBIDE SUBSTRATE

(75) Inventors: Satomi ITOH, Osaka-shi (JP); Takeyoshi MASUDA, Osaka-shi (JP); Makoto SASAKI, Itami-shi (JP); Shin HARADA, Osaka-shi (JP)

(73) Assignee: SUMITOMO ELECTRIC INDUSTRIES, LTD., Osaka-shi (JP)

(21) Appl. No.: 13/102,578

(22) Filed: May 6, 2011

(30) Foreign Application Priority Data
May 20, 2010 (JP) 2010-116231

(51) Int. Cl. H01L 21/306

(52) U.S. Cl. 438/455; 257/E21.215

(57) ABSTRACT

First and second supported portions each made of silicon carbide and a supporting portion made of silicon carbide are arranged such that the first and second supported portions and the supporting portion face each other and a gap is provided between the first and second supported portions. By sublimating and recrystallizing silicon carbide of the supporting portion, the supporting portion is connected to each of the first and second single-crystal substrates. On this occasion, a through hole is formed in the supporting portion so as to be connected to the gap. Accordingly, a path is formed which allows a fluid to pass through the gap and the through hole. By closing this path, the fluid can be prevented from being leaked through the silicon carbide substrate.

### BACKGROUND OF THE INVENTION

1. Field of the Invention

The present invention relates to a method for manufacturing a silicon carbide substrate.

2. Description of the Background Art

In recent years, silicon carbide substrates have been adopted as semiconductor substrates for use in manufacturing semiconductor devices. Silicon carbide has a band gap larger than that of silicon, which has been used more commonly. Hence, a semiconductor device employing a silicon carbide substrate advantageously has a large reverse breakdown voltage, low on-resistance, and properties less likely to decrease in a high temperature environment.

In order to efficiently manufacture such semiconductor devices, the substrates need to be large in size to some extent. According to U.S. Pat. No. 7,314,520, a silicon carbide substrate of 76 mm (3 inches) or greater can be manufactured.

Industrially, the size of a silicon carbide substrate is still limited to approximately 100 mm (4 inches). Accordingly, semiconductor devices cannot be efficiently manufactured using large substrates, disadvantageously. This disadvantage becomes particularly serious in the case of using a property of a plane other than the (0001) plane in silicon carbide of hexagonal system. Hereinafter, this will be described.

A silicon carbide substrate small in defect is usually manufactured by slicing a silicon carbide ingot obtained by growth in the (0001) plane, which is less likely to cause stacking fault. Hence, a silicon carbide substrate having a plane orientation other than the (0001) plane is obtained by slicing the ingot not in parallel with its grown surface. This makes it difficult to sufficiently secure the size of the substrate, or many portions in the ingot cannot be used effectively. For this reason, it is particularly difficult to effectively manufacture a semiconductor device that employs a plane other than the (0001) plane of silicon carbide.

Instead of increasing the size of a silicon carbide substrate with difficulty, it is being considered to use a silicon carbide substrate having a supporting portion made of silicon carbide, and a plurality of silicon carbide single-crystals (supported portions) disposed at different locations thereon. Even if the supporting portion has a low crystal defect density, problems are unlikely to take place. Hence, a large supporting portion can be prepared relatively readily. The size of the silicon carbide substrate can be increased by increasing the number of supported portions disposed on the supporting portion, as required.

The present inventors have found that a method of sublimating silicon carbide of the supporting portion and thereafter recrystallizing it on the supported portions can be used as a method for connecting the supporting portion and each of the supported portions to each other. It has been also found that the utilization of this method may cause through holes to be formed in the supporting portion and connected to a gap between adjacent supported portions. The through holes thus formed may cause leakage of a fluid flowing through a path formed by each through hole and the gap, upon manufacturing a semiconductor device using the silicon carbide substrate. An example of such leakage considered is leakage of a photoresist liquid or leakage of a gas to a vacuum portion of a vacuum chuck.

### SUMMARY OF THE INVENTION

The present invention has been made in view of the above-described problem, and its object is to provide a method for manufacturing a silicon carbide substrate, whereby a fluid can be prevented from being leaked through the silicon carbide substrate.

A method for manufacturing a silicon carbide substrate in the present invention includes the following steps. There is prepared a supporting portion having first and second main surfaces opposite to each other and made of silicon carbide. There is prepared a first supported portion having a first backside surface, a first front-side surface opposite to the first backside surface, and a first side surface connecting the first backside surface and the first front-side surface to each other. The first supported portion is made of silicon carbide. There is prepared a second supported portion having a second backside surface, a second front-side surface opposite to the second backside surface, and a second side surface connecting the second backside surface and the second front-side surface to each other. The second supported portion is made of silicon carbide. The supporting portion and the first and second supported portions are arranged such that each of the first and second backside surfaces faces the first main surface and the first and second side surfaces face each other with a gap interposed therebetween. The first main surface of the supporting portion is connected to each of the first and second backside surfaces by recrystallizing, on each of the first and second backside surfaces, a gas formed by sublimating silicon carbide of the supporting portion. In the step of connecting, a through hole is formed. The through hole extends between the first and second main surfaces in the supporting portion and is connected to the gap, resulting in a path which allows a fluid to pass through each of the gap and the through hole. Then, the path is closed.

According to the method for manufacturing, problems resulting from the leakage of the fluid via the path can be prevented upon manufacturing a semiconductor device using the silicon carbide substrate.

Preferably, the step of closing the path includes the step of filling the through hole. Accordingly, the path can be closed within the through hole.

Preferably, the step of filling the through hole includes the following steps. A melt containing silicon as a main component thereof is introduced into the through hole. Silicon carbide is grown in the through hole having the melt introduced therein, so as to close the through hole. In this way, the through hole can be filled more securely.

Preferably, the step of growing silicon carbide includes the step of heating the supporting portion for a predetermined time at a temperature equal to or higher than a melting point at which the melt is obtained. Accordingly, silicon carbide can be grown more securely in the through hole.

Preferably, in the above-described method for manufacturing the silicon carbide substrate, a solidified material of the melt is removed after growing silicon carbide. Accordingly, problems resulting from the solidified material of the melt can be prevented upon manufacturing a semiconductor device using the silicon carbide substrate.

Preferably, the step of removing the solidified material is performed by wet etching which employs an etchant. Accordingly, the solidified material can be removed readily.

More preferably, the etchant contains hydrofluoric-nitric acid. Accordingly, the solidified material containing silicon as its main component can be etched while avoiding damages on the portions made of silicon carbide.

Preferably, in the method for manufacturing the silicon carbide substrate, at least a portion of a surface of the silicon carbide substrate having the first and second supported portions and the supporting portion is polished after removing the solidified material. Accordingly, undesired objects, formed upon growing silicon carbide using the silicon carbide substrate, other than the above-described solidified material can be removed.

Preferably, in the method for manufacturing the silicon carbide substrate, at least a portion of a surface of the silicon carbide substrate having the first and second supported portions and the supporting portion is polished after growing silicon carbide. Accordingly, undesired objects can be removed which have been formed upon growing silicon carbide.

Preferably, the melt is introduced via the gap. Accordingly, the melt can be led to the through hole via the gap.

Preferably, the melt is introduced from the second main surface. Accordingly, the melt does not need to be supplied from the first and second front-side surfaces, thereby restraining damages on the first and second front-side surfaces.

Preferably, the step of introducing the melt includes the following steps. A material portion formed of a solid containing silicon as a main component thereof is provided on the silicon carbide substrate having the first and second supported portions and the supporting portion. The melt is generated by heating the material portion to reach or exceed a melting point of the material portion. Accordingly, the melt to be introduced into the through hole can be readily generated on the silicon carbide substrate.

Preferably, the step of providing the material portion is performed by placing a material piece, which serves as the material portion, on the silicon carbide substrate. Accordingly, the melt can be generated more readily.

Preferably, the step of providing the material portion is performed by forming a material film, which serves as the material portion, on the silicon carbide substrate. Accordingly, by adjusting the thickness of the material film, an amount of the melt generated can be adjusted with precision.

Preferably, the step of closing the path includes the step of covering at least one end of the path. Accordingly, the leakage of the fluid via the path can be prevented without filling the inside of the minute through hole.

Preferably, the step of covering includes the step of forming a cover for closing an opening between the first and second front-side surfaces and exposing at least a portion of each of the first and second front-side surfaces. Accordingly, the cover formed in the step of covering can be positioned in a location in which it is unlikely to be an obstacle in manufacturing a semiconductor device using the silicon carbide substrate.

Preferably, the step of covering includes the step of forming a cover on the second main surface. Accordingly, the through hole can be covered directly.

Preferably, the step of covering is performed using one or more materials selected from a group consisting of TaC, TiC, WC, VC, ZrC, NbC, MoC, HfC, and TiN. Accordingly, the cover formed in the step of covering can reduce an adverse effect on the manufacturing of a semiconductor device using the silicon carbide substrate.

Preferably, the step of covering is performed using at least one of a sputtering method and an evaporation method. Accordingly, the step of covering can be performed readily.

In the description above, the first and second supported portions are illustrated. This is not intended to exclude an embodiment having one or more additional supported portions in addition to the first and second supported portions.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a silicon carbide substrate in a first embodiment of the present invention.

FIG. 2 is a schematic cross sectional view taken along a line II-II in FIG. 1.

FIG. 3 is a top view schematically showing a first step of a method for manufacturing the silicon carbide substrate in the first embodiment of the present invention.

FIG. 4 is a schematic bottom view of FIG. 3.

FIG. 5 is a schematic cross sectional view taken along a line V-V in FIG. 3 and FIG. 4.

FIGS. 6-11 are partial cross sectional views schematically showing second to seventh steps of the method for manufacturing the silicon carbide substrate in the first embodiment of the present invention.

FIG. 12 is a cross sectional view schematically showing a first step of a method for manufacturing a silicon carbide substrate in a second embodiment of the present invention.

FIG. 13 is a partial enlarged view of FIG. 12.

FIG. 14 is a cross sectional view schematically showing a second step of the method for manufacturing the silicon carbide substrate in the second embodiment of the present invention, so as to illustrate how silicon carbide is transferred.

FIG. 15 is a cross sectional view schematically showing the second step of the method for manufacturing the semiconductor substrate in the second embodiment of the present invention, so as to illustrate how a vacant space is transferred.

FIG. 16 shows how a space is transferred in the cross section of FIG. 15.

FIGS. 17-21 are cross sectional views schematically showing first to fifth steps of a method for manufacturing a silicon carbide substrate in a third embodiment of the present invention.

FIG. 22 is a plan view schematically showing a first step of a method for manufacturing a silicon carbide substrate in a fourth embodiment of the present invention.

FIG. 23 is a schematic cross sectional view taken along a line XXIII-XXIII in FIG. 22.

FIG. 24 is a partial cross sectional view schematically showing one step of a method for manufacturing a semiconductor device in a fifth embodiment of the present invention.

FIG. 25 is a partial cross sectional view schematically showing a configuration of a semiconductor device in a sixth embodiment of the present invention.

FIG. 26 is a schematic flowchart showing a method for manufacturing the semiconductor device in the sixth embodiment of the present invention.

FIGS. 27-31 are partial cross sectional views schematically showing first to fifth steps of the method for manufacturing the semiconductor device in the sixth embodiment of the present invention.

FIG. 32 is a partial cross sectional view schematically showing one step of the method for manufacturing the semiconductor device in the seventh embodiment of the present invention.

FIGS. 33-37 are partial cross sectional views schematically showing first to fifth steps of a method for manufacturing a semiconductor device in an eighth embodiment of the present invention.

FIG. 38 is a partial cross sectional view schematically showing one step of a method for manufacturing a semiconductor device in a ninth embodiment of the present invention.

### DESCRIPTION OF THE PREFERRED EMBODIMENTS

The following describes embodiments of the present invention with reference to figures.

### First Embodiment

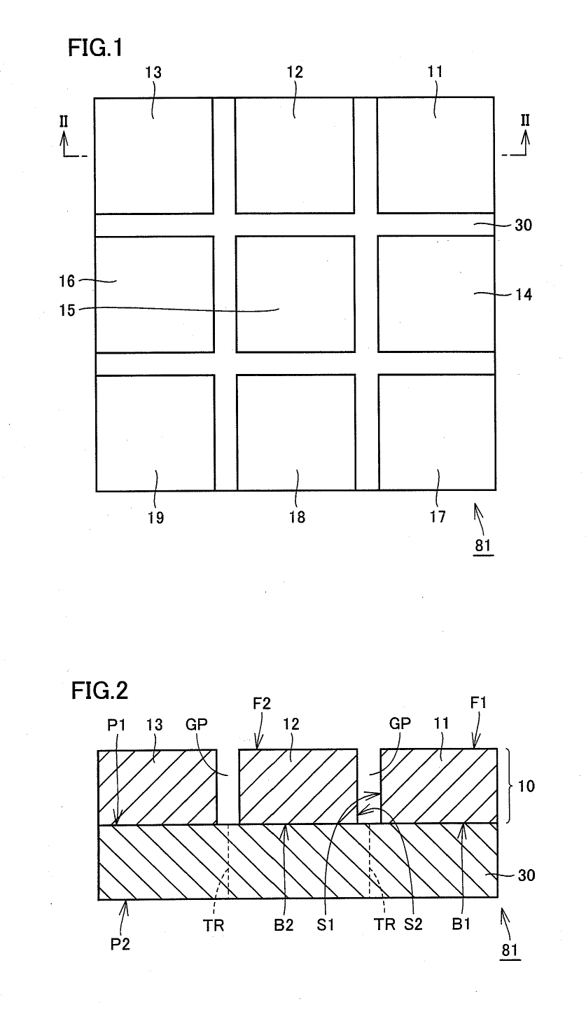

As shown in FIG. 1 and FIG. 2, a silicon carbide substrate 81 of the present embodiment has a supporting substrate 30 (supporting portion), and single-crystal substrates 11-19 (supported portions) supported by supporting substrate 30. Single-crystal substrates 11-19 are also collectively referred to as “single-crystal substrate group 10”.

Supporting substrate 30 connects the backside surfaces of single-crystal substrates 11-19 (surfaces opposite to the surfaces shown in FIG. 1) to one another, whereby single-crystal substrates 11-19 are fixed to one another. Single-crystal substrates 11-19 respectively have exposed front-side surfaces on the same plane. For example, single-crystal substrates 11 and 12 respectively have front-side surfaces F1 and F2 (first and second front-side surfaces). In this way, silicon carbide substrate 81 has a front-side surface larger than that of each one in single-crystal substrates 11-19. Hence, in the case of using silicon carbide substrate 81, semiconductor devices can be manufactured more effectively than in the case of using each one in single-crystal substrates 11-19 solely.

Supporting substrate 30 is made of silicon carbide, and has a main surface P1 (first main surface) and a main surface P2 (second main surface).

Each of single-crystal substrates 11-19 is made of silicon carbide, has a backside surface and a front-side surface opposite to each other, and has side surfaces connecting the backside surface and the front-side surface to each other. For example, single-crystal substrate 11 (first supported portion) has backside surface B1 (first backside surface) and front-side surface F1 (first front-side surface) opposite to each other, as well as a side surface S1 (first side surface) connecting backside surface B1 and front-side surface F1 to each other. Single-crystal substrate 12 (second supported portion) has backside surface B2 (second backside surface) and front-side surface F2 (second front-side surface) opposite to each other, as well as a side surface S2 (second side surface) connecting backside surface B2 and front-side surface F2 to each other.

Further, each of single-crystal substrates 11-19 is disposed on supporting substrate 30. Each of the backside surfaces (backside surfaces B1, B2, and the like) of single-crystal substrates 11-19 is connected to main surface P1 of supporting substrate 30. Furthermore, gaps GP are formed between adjacent ones of single-crystal substrates 11-19. Thus, for example, side surfaces S1 and S2 face each other with gap GP interposed therebetween. It should be noted that gaps GP do not need to separate single-crystal substrates 11-19 from one another completely. For example, side surface S1 may have a portion in contact with a portion of side surface S2.

In supporting substrate 30, closing portions TR are formed to extend between main surfaces P1, P2 and be connected to gaps GP. At least a portion of each closing portion TR is a portion obtained by filling a region of through hole by means of below-described regrowth of silicon carbide in supporting substrate 30. As such, in supporting substrate 30 of silicon carbide substrate 81, at least a portion of the region of through hole is filled, thereby preventing passage of fluid via the through hole.

The following describes a method for manufacturing silicon carbide substrate 81.

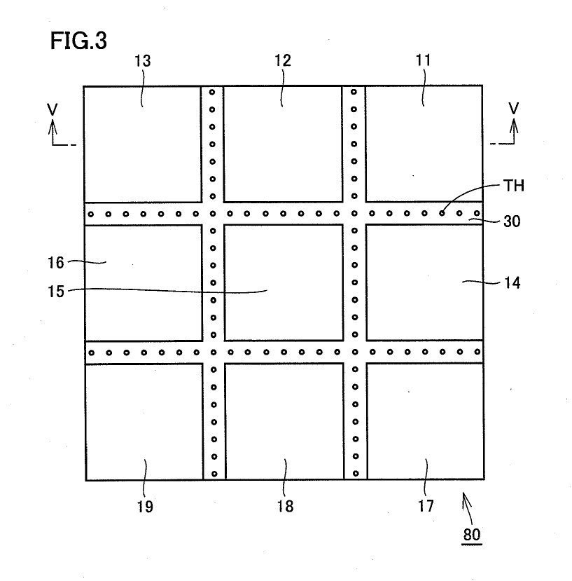

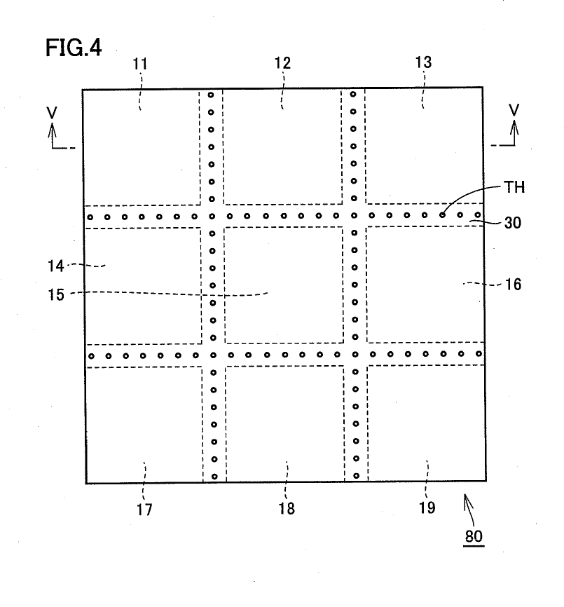

Referring to FIG. 3-FIG. 5, a silicon carbide substrate 80 is first prepared. Silicon carbide substrate 80 includes supporting substrate 30 having through holes TH which have not been filled yet. Each of through holes TH extends between main surfaces P1 and P2 in supporting substrate 30 and is connected to gap GP. Accordingly, in silicon carbide substrate 80, paths PT are formed to allow a fluid to pass through each of gaps GP and through holes TH. Accordingly, upon manufacturing semiconductor devices using silicon carbide substrate 80, a photoresist liquid may be leaked via paths PT or leakage of a gas to a vacuum portion may take place in vacuum chucking for silicon carbide substrate 81, for example.

It should be noted that a method for manufacturing silicon carbide substrate 80 and a reason for the generation of through holes TH will be described in a second embodiment. It should be also noted that the size of each through hole TH is exaggerated. Generally, through hole TH is hardly observed with eyes. Existence of through holes TH can be confirmed by, for example, providing a pressure difference between the supporting substrate 30 side and the single-crystal substrate group 10 side of silicon carbide substrate 80, and pouring a liquid to one of these sides. Thus, the existence thereof can be confirmed indirectly by the liquid leaking to the other side via path PT constituted by through hole TH and gap GP.

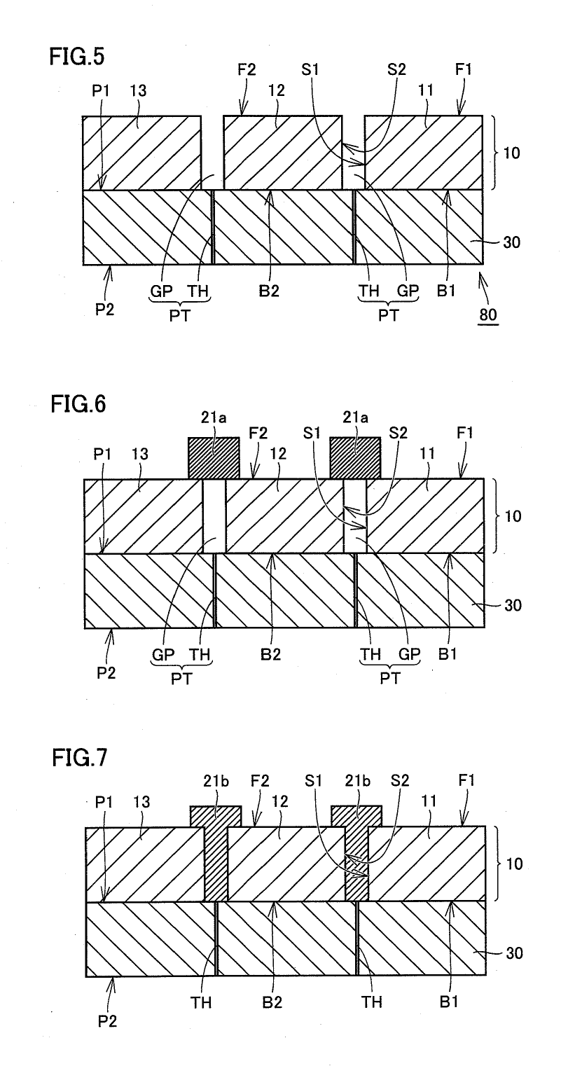

Referring to FIG. 6, silicon pieces 21a (material pieces) are placed on silicon carbide substrate 80 (FIG. 5). Each of silicon pieces 21a is placed thereon such that at least a portion of its bottom faces each gap GP. The existence of gap GP can be specified readily as compared with specifying the existence of through hole TH. Hence, the location facing gap GP, i.e., the location on which each silicon piece 21a should be placed can be readily specified. Any silicon piece 21a can be used as long as it has a melting point lower than the sublimation temperature of silicon carbide (approximately 1800° C.-2500° C.). For example, silicon piece 21a is made of pure silicon or silicon containing an additive. For example, silicon piece 21a is a member obtained by cutting a silicon substrate having a thickness of 100-400 μm, and has a width of approximately 1 mm and a length corresponding to the length of gap GP (FIG. 5) when viewed in a planar view (FIG. 3).

Referring to FIG. 7, silicon piece 21a is heated to reach or exceed its melting point. Exemplary conditions for this heating are as follows: heating temperature is 1500° C., heating time is 10 minutes, and heating atmosphere is Ar atmosphere, Si atmosphere, or H₂—Si—C atmosphere. Accordingly, a melt 21b is generated from each silicon piece 21a. Melt 21b enters gap GP and reaches main surface P1 of supporting substrate 30. Melt 21b thus having reached main surface P1 readily enters through hole TH because the material of supporting substrate 30, i.e., silicon carbide, has a good wettability for such a silicon melt.

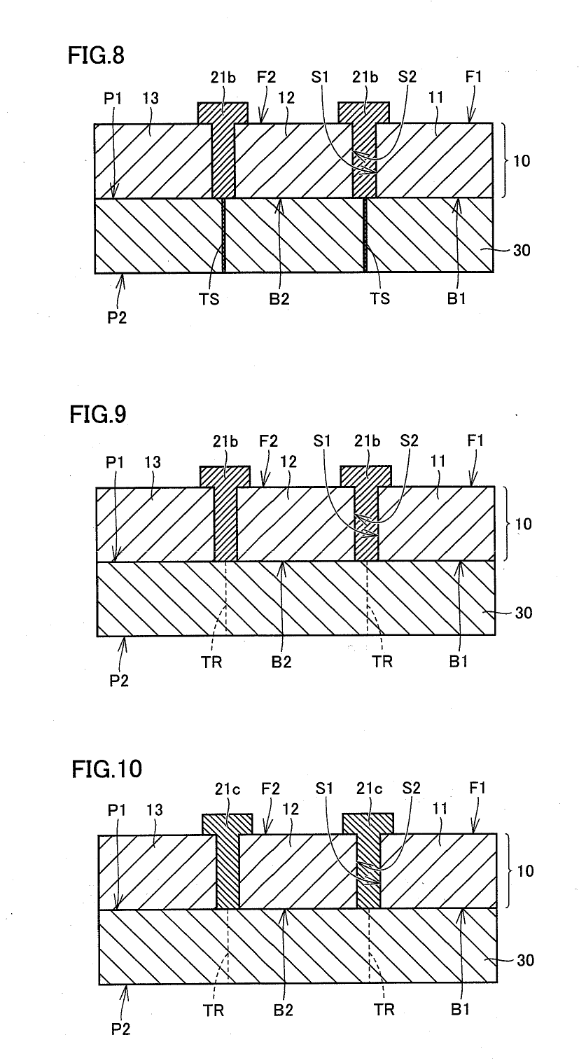

Referring to FIG. 8, melt 21b thus having entered is introduced into through hole TH, thereby forming at least a portion of the region of through hole TH (FIG. 7) into a melt portion TS.

Referring to FIG. 9, in melt portion TS, i.e., through hole TH having melt 21b introduced therein, silicon carbide is grown to close through hole TH. Specifically, liquid phase epitaxial growth of supporting substrate 30 takes place in melt portion TS, thereby filling through hole TH therewith. In this way, through hole TH is closed. In order to securely grow silicon carbide in through hole TH, supporting substrate 30 is heated for a predetermined time at a temperature of not less than the melting point at which melt 21b is obtained. Preferably, this predetermined time is longer as the size of through hole TH is larger.

Referring to FIG. 10, the temperature of melt 21b (FIG. 9) is decreased to solidify melt 21b, thereby forming a solidified material 21c.

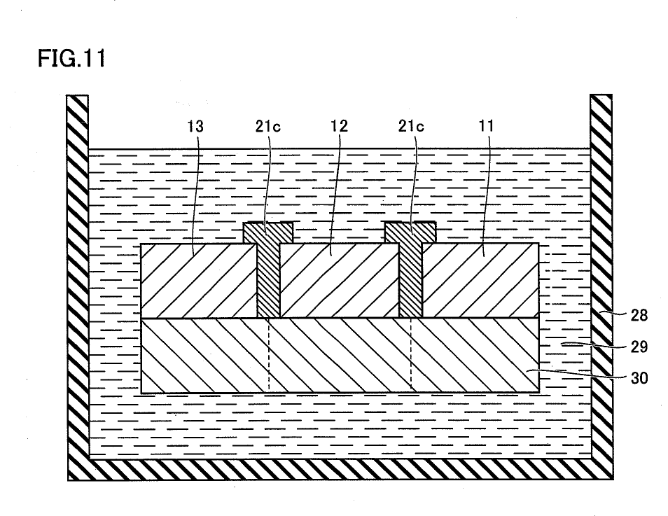

Referring to FIG. 11, etchant 29 is accumulated in container 28. Etchant 29 is capable of melting solidified material 21c at a sufficient rate, and causes less damage on silicon carbide. Etchant 29 contains hydrofluoric-nitric acid, for example. Next, solidified material 21c is immersed in etchant 29. In this way, solidified material 21c is wet-etched and is accordingly removed.

Accordingly, silicon carbide substrate 81 (FIG. 2) is obtained. Preferably, the front-side surfaces (front-side surfaces F1, F2, and the like) of single-crystal substrate group 10 are polished. This not only flattens the front-side surfaces but also removes silicon carbide grown on the front-side surfaces upon the above-described heating step. Further, main surface P2 of supporting substrate 30 is also polished as required.

According to the present embodiment, through holes TH (FIG. 5) are closed to form closing portions TR. This prevents leakage of a fluid flowing via paths PT (FIG. 5) upon manufacturing semiconductor devices using silicon carbide substrate 81. Thus, problems resulting from this leakage can be prevented.

As described above, paths PT are closed within through holes TH. Hence, the external surface of silicon carbide substrate 81 (FIG. 2) can be substantially the same as the external surface of silicon carbide substrate 80. That is, no member needs to be provided on the external surface of silicon carbide substrate 80.

### Second Embodiment

In the present embodiment, the following describes a method for manufacturing silicon carbide substrate 80 (FIG. 3-FIG. 5), which is used in the method for manufacturing silicon carbide substrate 81 in the first embodiment. It should be noted that the same or corresponding elements as those in the first embodiment are given the same reference characters and are not described repeatedly. In addition, for ease of description, only single-crystal substrates 11 and 12 of single-crystal substrates 11-19 may be explained, but the same explanation also applies to single-crystal substrates 13-19.

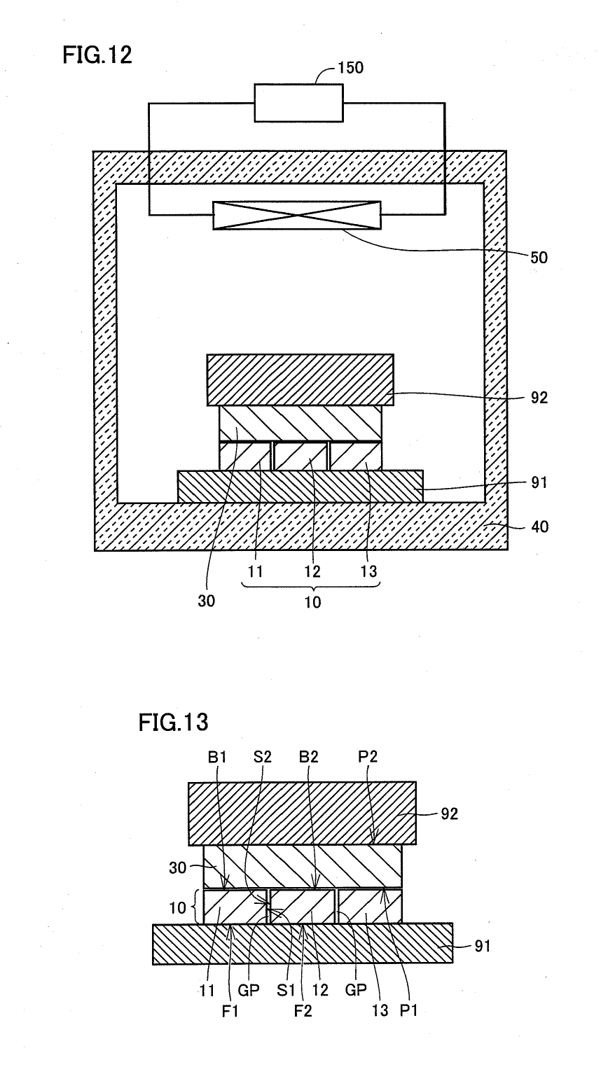

Referring to FIG. 12 and FIG. 13, supporting substrate 30, single-crystal substrates 11-19, i.e., single-crystal substrate group 10, and a heating device are prepared.

Each of single-crystal substrates 11-19 is prepared by cutting, along the (03-38) plane, a SiC ingot grown in the (0001) plane in the hexagonal system. In this case, preferably, the (03-38) plane side is employed for the backside surface thereof, and the (0-33-8) plane side is employed for the front-side surface thereof.

The heating device has first and second heating members 91, 92, a heat insulation container 40, a heater 50, and a heater power source 150. Heat insulation container 40 is formed of a highly thermally insulating material. Heater 50 is, for example, an electric resistance heater. First and second heating members 91, 92 have a function of absorbing heat emitted from heater 50 and emitting the absorbed heat so as heat supporting substrate 30 and single-crystal substrate group 10. Each of first and second heating members 91, 92 is formed of, for example, graphite with a small porosity.

Next, first heating member 91, single-crystal substrate group 10, supporting substrate 30, and second heating member 92 are arranged to be stacked on one another in this order. Specifically, first, single-crystal substrates 11-19 are arranged on first heating member 91 in the form of a matrix. For example, single-crystal substrates 11 and 12 are placed thereon such that their side surfaces S1 and S2 face each other with gap GP interposed therebetween. Next, supporting substrate 30 is placed on the front-side surface of single-crystal substrate group 10. Then, second heating member 92 is placed on supporting substrate 30. Then, the first heating member, single-crystal substrate group 10, supporting substrate 30, and the second heating member thus stacked on one another are accommodated in heat insulation container 40 having heater 50 provided therein.

Next, the atmosphere in heat insulation container 40 is adapted to be an atmosphere obtained by reducing the pressure of atmospheric air, or an inert gas atmosphere. An exemplary inert gas usable is a noble gas such as He or Ar; a nitrogen gas; or a mixed gas of the noble gas and nitrogen gas. Further, the pressure in heat insulation container 40 is preferably 50 kPa or smaller, and is more preferably 10 kPa or smaller.

Next, heater 50 heats, by means of first and second heating members 91, 92, single-crystal substrate group 10 and supporting substrate 30 to a temperature at which sublimation/recrystallization reaction takes place, for example, a temperature of not less than 1800° C. and not more than 2500° C. This heating is performed to cause a temperature difference such that the temperature of supporting substrate 30 becomes higher than the temperature of single-crystal substrate group 10. Such a temperature difference can be obtained by providing a temperature gradient in heat insulation container 40. This temperature gradient is, for example, not less than 0.1° C./mm and not more than 100° C./mm.

Referring to FIG. 14, at the stage of starting the heating, supporting substrate 30 is only placed on each of single-crystal substrates 11 and 12, and is not connected thereto. Thus, when viewed microscopically, a space GQ exists between each of the backside surfaces of single-crystal substrates 11 and 12 (FIG. 13: backside surfaces B1 and B2) and main surface P1 of supporting substrate 30. Space GQ has an average height (dimension in the vertical direction in FIG. 14) of several ten μm, for example.

As described above, when the temperature of supporting substrate 30 is adapted to be higher than that of each of single-crystal substrates 11 and 12, this temperature gradient causes mass transfer of silicon carbide, involved in the sublimation and recrystallization. Specifically, sublimation gas of silicon carbide is formed from supporting substrate 30, and this gas is recrystallized on each of single-crystal substrates 11 and 12. In other words, mass transfer takes place in space GQ from supporting substrate 30 to each of single-crystal substrates 11 and 12 as indicated by arrows Mc in the figure. Meanwhile, as indicated by an arrow Mb in the figure, mass transfer takes place from supporting substrate 30 to gap GP.

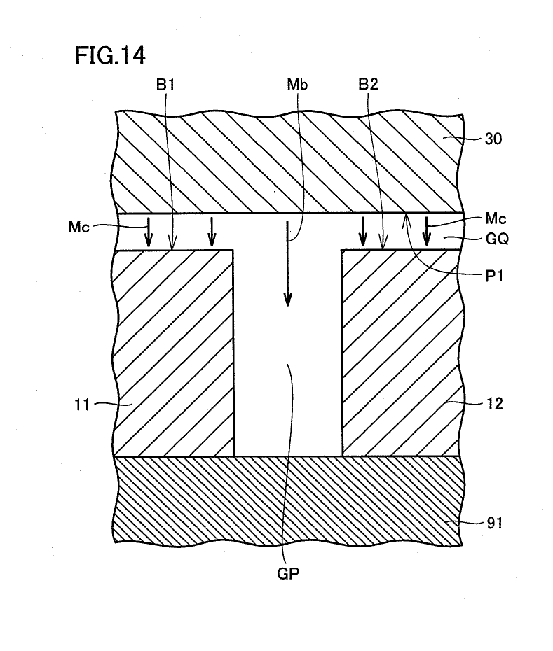

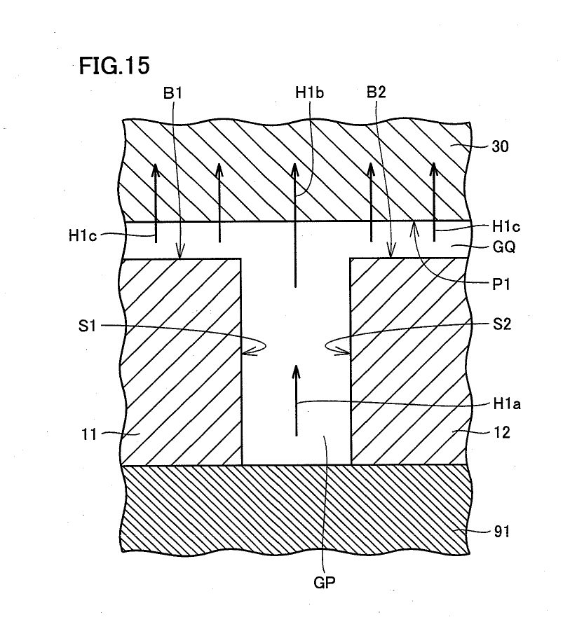

Conversely, referring to FIG. 15, the mass transfers indicated by arrows Mb and Mc (FIG. 14) correspond to transfer of vacant spaces existing in gap GP and space GQ as indicated by arrows H1b and H1c (FIG. 15). Here, there is a large in-plane variation in the height of space GQ (dimension in the vertical direction in the figure), and this variation results in a large in-plane variation in a rate of transfer of the vacant space corresponding to space GQ (arrows H1c in the figure).

Further, referring to FIG. 16, due to the variation, the vacant space corresponding to space GQ (FIG. 15) cannot keep its shape upon being transferred, resulting in generation of a plurality of voids Vc (FIG. 16). Voids Vc are transferred due to the above-described temperature gradient as indicated by arrows H2c (FIG. 16) to reach main surface P2 (FIG. 13) of supporting substrate 30, thereby being eliminated therefrom.

Further, the transfer of the vacant space corresponding to gap GP as indicated by H1b (FIG. 15) allows a vacant space Vb connected to gap GP to extend from main surface P1 into supporting substrate 30 as indicated by an arrow H2b (FIG. 16). Because vacant space Vb is generated from gap GP having a much larger height than that of space GQ, vacant space Vb keeps on being generated uninterruptedly to form through hole TH (FIG. 3-FIG. 5).

Accordingly, when main surface P1 of supporting substrate 30 is connected to each of backside surfaces B1, B2, silicon carbide substrate 80 having through hole TH is obtained.

Preferably, supporting substrate 30 has an impurity concentration higher than that of each in single-crystal substrates 11-19. In other words, the impurity concentration of supporting substrate 30 is relatively high and the impurity concentration of each of single-crystal substrates 11-19 is relatively low. Since the impurity concentration of supporting substrate 30 is thus high, the resistivity of supporting substrate 30 can be small, thereby reducing a resistance for current flowing in silicon carbide substrate 81. Meanwhile, since the impurity concentration of each of single-crystal substrates 11-19 is thus low, the crystal defect thereof can be reduced more readily. As the impurity, nitrogen or phosphorus can be used, for example.

The crystal structure of silicon carbide of single-crystal substrate 11 is preferably of hexagonal system, and is more preferably of 4H type or 6H type. More preferably, front-side surface F1 has an off angle of not less than 50° and not more than 65° relative to the {0001} plane of single-crystal substrate 11. More preferably, the off orientation of front-side surface F1 forms an angle of 5° or smaller with the <1-100> direction of single-crystal substrate 11. More preferably, front-side surface F1 has an off angle of not less than −3° and not more than 5° relative to the {03-38} plane in the <1-100> direction of single-crystal substrate 11. Utilization of such a crystal structure achieves high channel mobility in a semiconductor device that employs silicon carbide substrate 80. It should be noted that the “off angle of front-side surface F1 relative to the {03-38} plane in the <1-100> direction” refers to an angle formed by an orthogonal projection of a normal line of front-side surface F1 to a projection plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction. Further, as a preferable off orientation of front-side surface F1, the following off orientation can be employed apart from those described above: an off orientation forming an angle of 5° or smaller relative to the <11-20> direction of single-crystal substrate 11. Further, the description above has illustrated the preferable exemplary crystal structure of silicon carbide of single-crystal substrate 11. The same applies to the other single-crystal substrates 12-19.

### Third Embodiment

Also in the present embodiment, silicon carbide substrate 81 substantially the same as that in the first embodiment is obtained. Hence, the same or corresponding elements as those in the first embodiment are given the same reference characters and are not described repeatedly. The following describes a manufacturing method in the present embodiment.

First, silicon carbide substrate 80 (FIG. 3-FIG. 5) is prepared in accordance with the method described in the second embodiment.

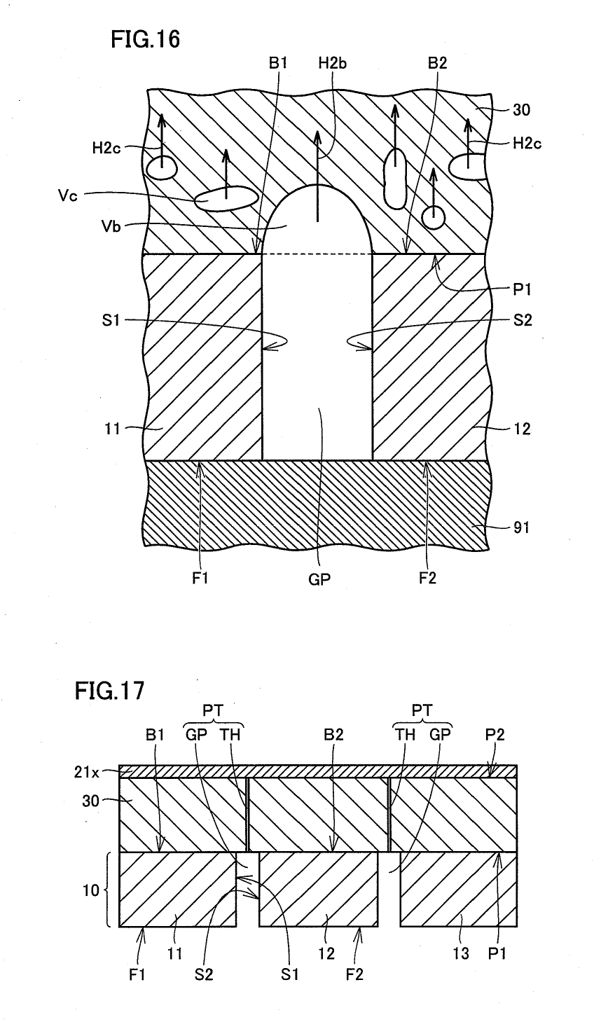

Referring to FIG. 17, a silicon film 21x (material film) is formed on main surface P2 of supporting substrate 30. As material for silicon film 21x, the same material as that for silicon piece 21a can be employed. Silicon film 21x preferably has a thicker thickness as the size of through hole TH is larger. For example, silicon film 21x has a thickness of 10 nm to 10 μm.

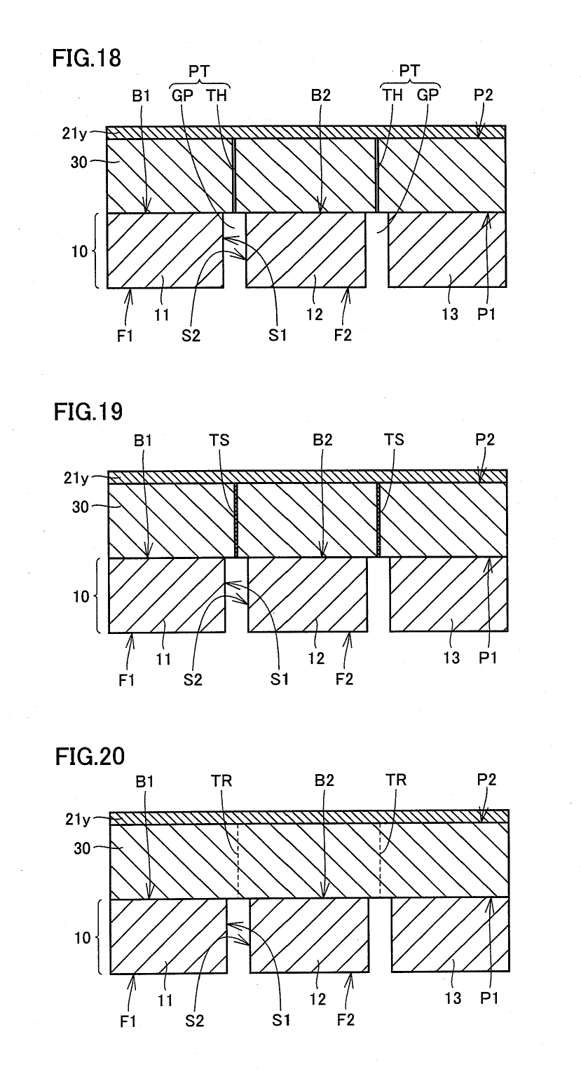

Referring to FIG. 18, silicon film 21x is heated to reach or exceed its melting point. Accordingly, a melt 21y is generated from silicon film 21x. Melt 21y enters each through hole TH from main surface P2. It should be noted that preferable heating conditions are the same as those in the first embodiment.

Referring to FIG. 19, melt 21y thus having entered is introduced into through hole TH (FIG. 18), thereby forming at least a portion of the region of through hole TH into a melt portion TS.

Referring to FIG. 20, in melt portion TS, i.e., through hole TH having melt 21b introduced therein, silicon carbide is grown to close through hole TH. Specifically, in melt portion TS, liquid phase epitaxial growth of supporting substrate 30 takes place to fill through hole TH therewith. In this way, through hole TH is closed. In order to grow silicon carbide in through hole TH more securely, supporting substrate 30 is heated for a predetermined time at a temperature equal to or higher than the melting point at which melt 21y is obtained.

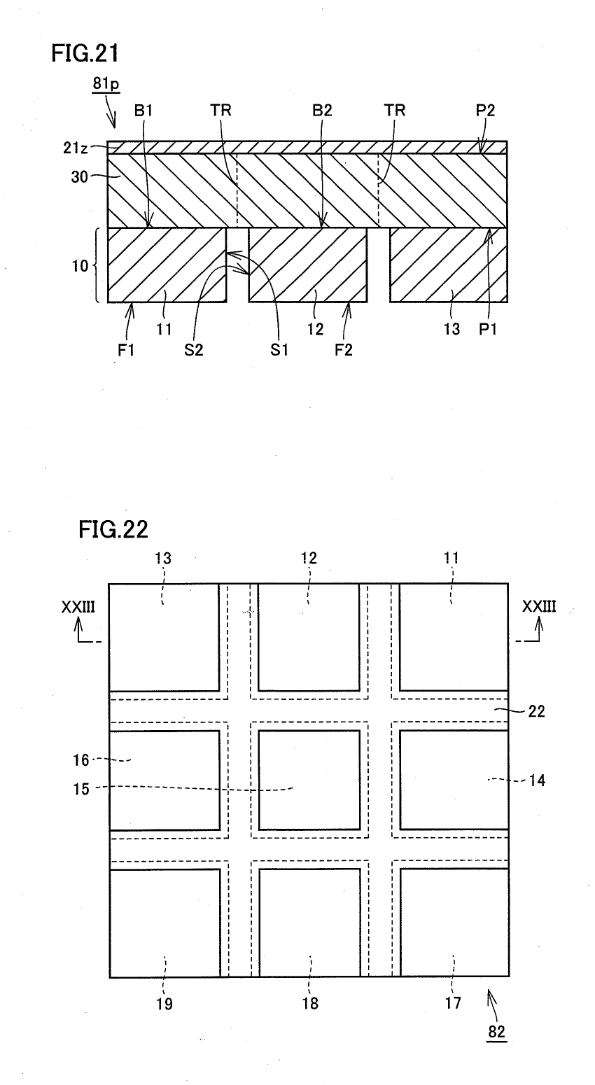

Referring to FIG. 21, by decreasing the temperature of melt 21y (FIG. 20), melt 21y is solidified to form a solidified material 21z. At this point of time, a silicon carbide substrate 81p is obtained which is configured to have solidified material 21z on main surface P2 of supporting substrate 30 of silicon carbide substrate 81. Next, as required, solidified material 21z is removed by, for example, polishing or the above-described wet etching. Accordingly, silicon carbide substrate 81 (FIG. 2) substantially the same as that of the first embodiment is obtained.

According to the present embodiment, the step (FIG. 18) of introducing melt 21y is performed from main surface P2. Accordingly, melt 21y does not need to be supplied from front-side surfaces F1, F2, thereby restraining damages on front-side surface F1, F2 due to contact thereof with melt 21y.

Further, melt 21y (FIG. 18) to be introduced into through hole TH can be readily formed on main surface P2 by heating silicon film 21x (FIG. 17) to reach or exceed its melting point.

Further, an amount of melt 21y generated (FIG. 18) can be adjusted with precision by adjusting the thickness of silicon film 21x (FIG. 17).

It should be noted that through hole TH (FIG. 18) may not be entirely filled with silicon carbide and the solidified material of melt 21y may remain in a part of through hole TH. This solidified material can be melted again when heated at a high temperature in manufacturing a semiconductor device using silicon carbide substrate 81. Also on this occasion, silicon carbide can be grown in through hole TH.

### Fourth Embodiment

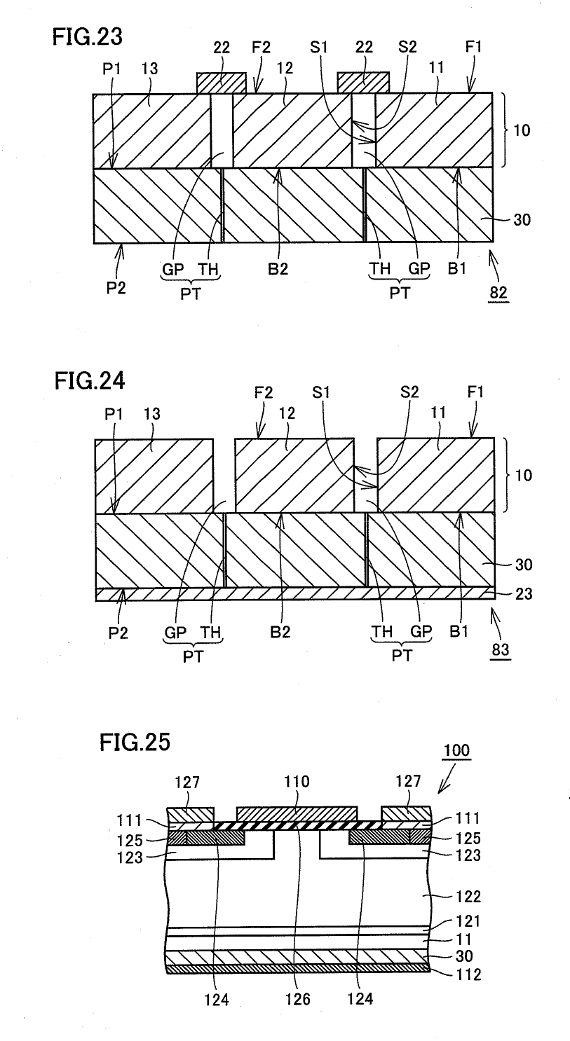

As shown in FIG. 22 and FIG. 23, a silicon carbide substrate 82 of the present embodiment is configured to have a cap film 22 (cover) provided in silicon carbide substrate 80 (FIG. 3-FIG. 5). Cap film 22 closes an opening between front-side surfaces F1 and F2 to cover the opening of each gap GP. In this way, one end of each path PT is closed. Further, cap film 22 allows each of front-side surfaces F1 and F2 to be exposed partially. Cap film 22 is preferably made of a material less likely to cause an adverse effect upon manufacturing a semiconductor device using the silicon carbide substrate. Specifically, cap film 22 is preferably made of a material having a high heat resistance and a high chemical resistance. An example of such a material is TaC, TiC, WC, VC, ZrC, NbC, MoC, HfC, or TiN.

Cap film 22 is provided on silicon carbide substrate 80 by forming a film of the material of cap film 22 on a portion of the surface of the single-crystal substrate group 10 side of silicon carbide substrate 80 (FIG. 5). Such partial film formation can be achieved using, for example, a metal mask having an opening. As a film forming method, a sputtering method or an evaporation method is employed, for example.

According to the present embodiment, paths PT can be closed without filling minute through holes TH. Further, cap film 22 can be positioned at a location between the front-side surfaces F1 and F2 or a location in the vicinity thereof, i.e., at a location at which it is less likely to be an obstacle in manufacturing a semiconductor device using silicon carbide substrate 82. Further, cap film 22 can be removed simultaneously upon dicing. In this case, a step of only removing cap film 22 does not need to be performed. Further, the method for manufacturing silicon carbide substrate 82 can be implemented only by the partial film formation on silicon carbide substrate 80.

### Fifth Embodiment

As shown in FIG. 24, a silicon carbide substrate 83 of the present embodiment is configured to have a cap layer 23 (cover) provided in silicon carbide substrate 80 (FIG. 3-FIG. 5). Cap layer 23 is formed on main surface P2 of supporting substrate 30 and covers the opening of each through hole TH. In this way, one end of each path PT is closed. Cap layer 23 may cover main surface P2 entirely. Cap layer 23 can be made of the same material as that of cap film 22 (FIG. 23). As a method for forming the cap layer, the sputtering method or the evaporation method can be used, for example.

According to the present embodiment, paths PT can be closed without filling minute through holes TH. Further, unlike the fourth embodiment, cap layer 23 does not need to have an opening, and can be therefore readily formed.

### Sixth Embodiment

In the present embodiment, the following describes manufacturing of a semiconductor device employing silicon carbide substrate 81 (FIG. 1 and FIG. 2). For ease of description in sixth to ninth embodiments, only single-crystal substrate 11 of single-crystal substrates 11-19 provided in silicon carbide substrate 81 may be explained, but each of the other single-crystal substrates 12-19 is handled in substantially the same manner.

Referring to FIG. 25, a semiconductor device 100 of the present embodiment is a DiMOSFET (Double Implanted Metal Oxide Semiconductor Field Effect Transistor) of vertical type, and has supporting substrate 30, single-crystal substrate 11, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112. Semiconductor device 100 has a planar shape (shape when viewed from upward in FIG. 25) of for example, a rectangle or a square with sides each having a length of 2 mm or greater.

Drain electrode 112 is provided on supporting substrate 30 and buffer layer 121 is provided on single-crystal substrate 11. With this arrangement, a region in which flow of carriers is controlled by gate electrode 110 is disposed not in supporting substrate 30 but in single-crystal substrate 11.

Each of supporting substrate 30, single-crystal substrate 11, and buffer layer 121 has n type conductivity. Impurity with n type conductivity in buffer layer 121 has a concentration of, for example, 5×10¹⁷ cm⁻³. Further, buffer layer 121 has a thickness of, for example, 0.5 μm.

Reverse breakdown voltage holding layer 122 is formed on buffer layer 121, and is made of SiC with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. Oxide film 126 is formed on reverse breakdown voltage holding layer 122 exposed between the plurality of p regions 123. Specifically, oxide film 126 is formed to extend on n⁺ region 124 in one p region 123, p region 123, the exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of nitrogen atom concentration is 1×10²¹ cm⁻³ in a region distant away by 10 nm or shorter from an interface between oxide film 126 and each of the semiconductor layers, i.e., n⁺ regions 124, p⁺ regions 125, p regions 123, and reverse breakdown voltage holding layer 122. This achieves improved mobility particularly in a channel region below oxide film 126 (a contact portion of each p region 123 with oxide film 126 between each of n⁺ regions 124 and reverse breakdown voltage holding layer 122).

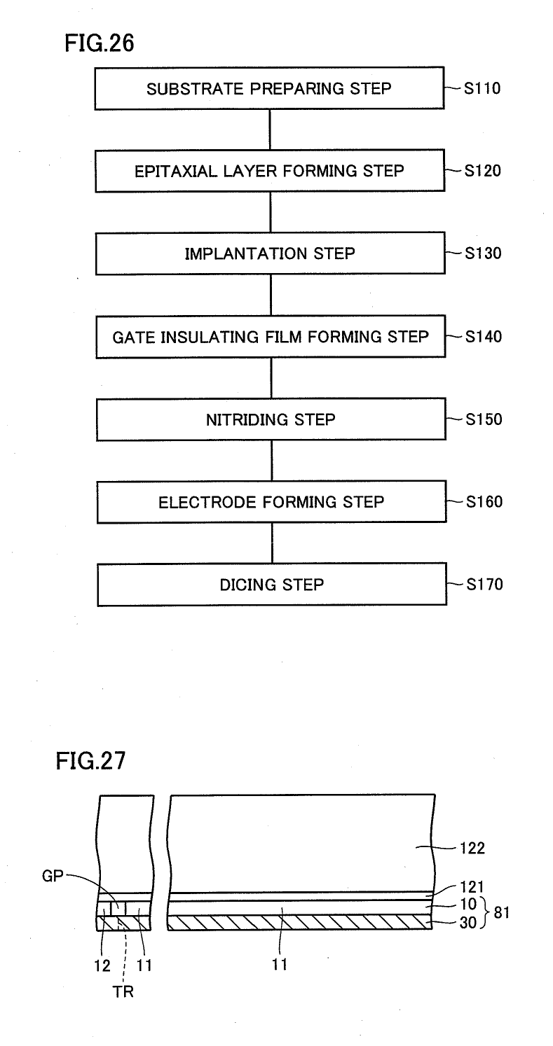

The following describes a method for manufacturing semiconductor device 100. First, in a substrate preparing step (step S110: FIG. 26), silicon carbide substrate 81 (FIG. 1 and FIG. 2) is prepared.

Referring to FIG. 27, in an epitaxial layer forming step (step S120: FIG. 26), buffer layer 121 and reverse breakdown voltage holding layer 122 are formed as follows.

First, buffer layer 121 is formed on the front-side surface of single-crystal substrate group 10. Buffer layer 121 is made of SiC of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121.

Specifically, a layer made of SiC of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of, for example, 5×10¹⁵ cm⁻³.

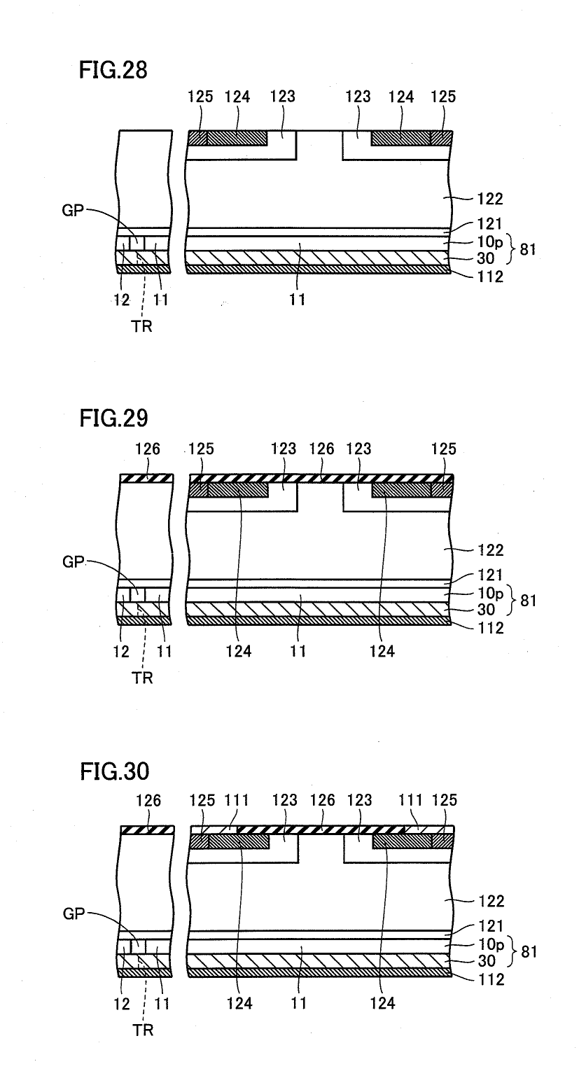

Referring to FIG. 28, an implantation step (step S130: FIG. 26) is performed to form p regions 123, n⁺ regions 124, and p⁺ regions 125 as follows.

First, a conductive impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 29, a gate insulating film forming step (step S140: FIG. 26) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitriding step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Referring to FIG. 30, an electrode forming step (step S160: FIG. 26) is performed to form source electrodes 111 and drain electrode 112 in the following manner.

First, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

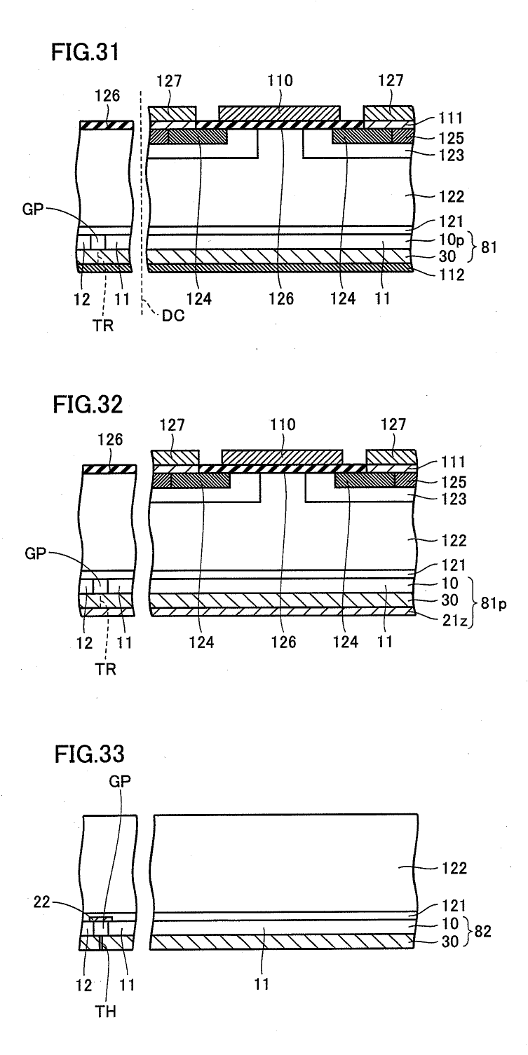

Referring to FIG. 31, upper source electrodes 127 are formed on source electrodes 111. Further, gate electrode 110 is formed on oxide film 126. Further, drain electrode 112 is formed on the backside surface of silicon carbide substrate 81.

Next, in a dicing step (step S170: FIG. 26), dicing is performed as indicated by a broken line DC. Accordingly, a plurality of semiconductor devices 100 (FIG. 25) are obtained by the cutting.

According to the method for manufacturing semiconductor device 100 in the present embodiment, silicon carbide substrate 81 obtained by closing through hole TH (FIG. 3-FIG. 5) of silicon carbide substrate 80 is used, thereby preventing leakage of a fluid through silicon carbide substrate 81. Prevented is leakage of a photoresist liquid, or leakage of a gas to a vacuum portion of a vacuum chuck, for example.

### Seventh Embodiment

In the present embodiment, the following describes semiconductor device 100 (FIG. 25) employing silicon carbide substrate 81p (FIG. 21).

Referring to FIG. 32, as with the sixth embodiment, epitaxial layer forming step S120, implantation step S130, gate insulating film forming step S140, and nitriding step S150 (FIG. 26) are performed. Further, source electrodes 111, upper source electrodes 127, and gate electrode 110 are formed. Next, in order to achieve low resistance of the semiconductor device, for example, a backgrind step, i.e., polishing is performed to reduce the thickness of supporting substrate 30. In the present embodiment, solidified material 21z is formed on supporting substrate 30. Hence, solidified material 21z is removed first by polishing, and then the thickness of supporting substrate 30 is reduced. Then, on the backside surface of supporting substrate 30, drain electrode 112 is formed. Thereafter, dicing step S170 (FIG. 26) is performed. In this way, semiconductor device 100 (FIG. 25) is obtained.

According to the method for manufacturing semiconductor device 100 in the present embodiment, a fluid is prevented from being leaked through silicon carbide substrate 81p. Further, in the backgrind step, solidified material 21z can be removed.

### Eighth Embodiment

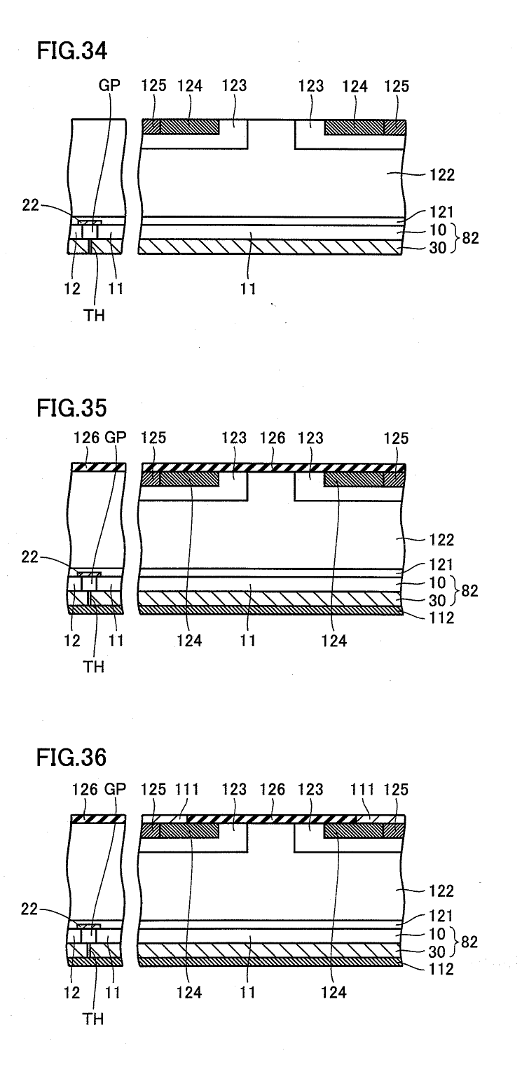

A method for manufacturing semiconductor device 100 (FIG. 25) of the present embodiment is substantially the same as that in the sixth embodiment, but employs silicon carbide substrate 82 (FIG. 33) instead of silicon carbide substrate 81 (FIG. 27). Apart from this, substantially the same steps as those in the sixth embodiment are performed as shown in FIG. 33-FIG. 37.

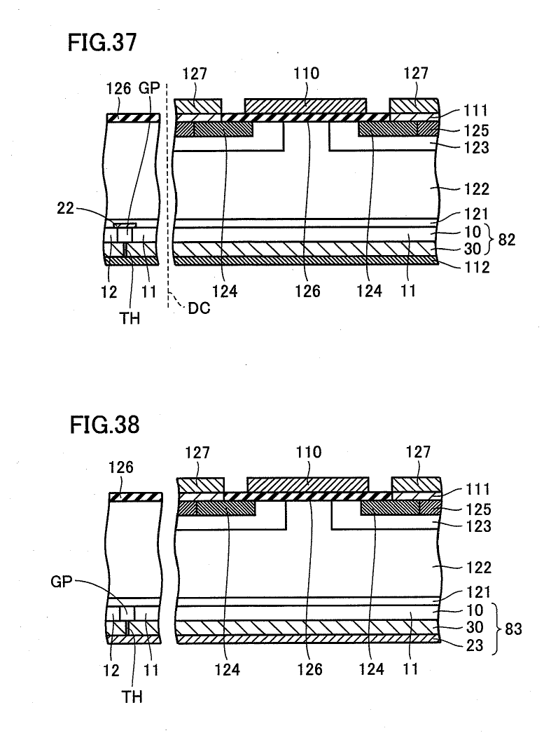

According to the method for manufacturing semiconductor device 100 in the present embodiment, a fluid is prevented from being leaked through silicon carbide substrate 82. Further, in the dicing step (step S170: FIG. 26; broken line DC: FIG. 37), cap film 22 can be removed.

### Ninth Embodiment

A method for manufacturing semiconductor device 100 (FIG. 25) of the present embodiment is substantially the same as that in the sixth embodiment, but employs silicon carbide substrate 83 (FIG. 38) instead of silicon carbide substrate 81 (FIG. 27).

Referring to FIG. 38, as with the sixth embodiment, epitaxial layer forming step S120, implantation step S130, gate insulating film forming step S140, and nitriding step S150 (FIG. 26) are performed. Further, source electrodes 111, upper source electrodes 127, and gate electrode 110 are formed. Next, in order to achieve low resistance of the semiconductor device, for example, a backgrind step, i.e., polishing is performed to reduce the thickness of supporting substrate 30. In the present embodiment, cap layer 23 is formed on supporting substrate 30. Hence, cap layer 23 is removed first by polishing, and then the thickness of supporting substrate 30 is reduced. Then, on the backside surface of supporting substrate 30, drain electrode 112 is formed. Thereafter, dicing step S170 (FIG. 26) is performed. In this way, semiconductor device 100 (FIG. 25) is obtained.

It should be noted that a configuration may be employed in which conductive types are opposite to those in each of the embodiments described above. Namely, a configuration may be employed in which p type and n type are replaced with each other. Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a supporting portion having first and second main surfaces opposite to each other and made of silicon carbide;
preparing a first supported portion having a first backside surface, a first front-side surface opposite to said first backside surface, and a first side surface connecting said first backside surface and said first front-side surface to each other, said first supported portion being made of silicon carbide;
preparing a second supported portion having a second backside surface, a second front-side surface opposite to said second backside surface, and a second side surface connecting said second backside surface and said second front-side surface to each other, said second supported portion being made of silicon carbide;
arranging said supporting portion and said first and second supported portions such that each of said first and second backside surfaces faces said first main surface and said first and second side surfaces face each other with a gap interposed therebetween;
connecting said first main surface to each of said first and second backside surfaces by sublimating silicon carbide of said supporting portion and then recrystallizing the silicon carbide on each of said first and second backside surfaces, in the step of connecting, a through hole being formed, said through hole extending between said first and second main surfaces in said supporting portion and connected to said gap, resulting in a path which allows a fluid to pass through each of said gap and said through hole; and
closing said path.

2. The method for manufacturing the silicon carbide substrate according to claim 1, wherein the step of closing said path includes the step of filling said through hole.

3. The method for manufacturing the silicon carbide substrate according to claim 2, wherein:
the step of filling said through hole includes the steps of
introducing, into said through hole, a melt containing silicon as a main component thereof, and
growing silicon carbide in said through hole having said melt introduced therein, so as to close said through hole.

4. The method for manufacturing the silicon carbide substrate according to claim 3, wherein the step of growing silicon carbide includes the step of heating said supporting portion for a predetermined time at a temperature equal to or higher than a melting point at which said melt is obtained.

5. The method for manufacturing the silicon carbide substrate according to claim 3, further comprising the step of removing a solidified material of said melt after the step of growing silicon carbide.

6. The method for manufacturing the silicon carbide substrate according to claim 5, wherein the step of removing said solidified material is performed by wet etching which employs an etchant.

7. The method for manufacturing the silicon carbide substrate according to claim 6, wherein said etchant contains hydrofluoric-nitric acid.

8. The method for manufacturing the silicon carbide substrate according to claim 5, further comprising the step of polishing at least a portion of a surface of the silicon carbide substrate having said first and second supported portions and said supporting portion, after the step of removing said solidified material.

9. The method for manufacturing the silicon carbide substrate according to claim 3, further comprising the step of polishing at least a portion of a surface of the silicon carbide substrate having said first and second supported portions and said supporting portion after the step of growing silicon carbide.

10. The method for manufacturing the silicon carbide substrate according to claim 3, wherein said melt is introduced via said gap.

11. The method for manufacturing the silicon carbide substrate according to claim 3, wherein said melt is introduced from said second main surface.

12. The method for manufacturing the silicon carbide substrate according to claim 3, wherein:
the step of introducing said melt includes the steps of
providing a material portion formed of a solid containing silicon as a main component thereof, on the silicon carbide substrate having said first and second supported portions and said supporting portion, and
generating said melt by heating said material portion to reach or exceed a melting point of said material portion.

13. The method for manufacturing the silicon carbide substrate according to claim 12, wherein the step of providing said material portion is performed by placing a material piece, which serves as said material portion, on said silicon carbide substrate.

14. The method for manufacturing the silicon carbide substrate according to claim 12, wherein the step of providing said material portion is performed by forming a material film, which serves as said material portion, on said silicon carbide substrate.

15. The method for manufacturing the silicon carbide substrate according to claim 1, wherein the step of closing said path includes the step of covering at least one end of said path.

16. The method for manufacturing the silicon carbide substrate according to claim 15, wherein the step of covering includes the step of forming a cover for closing an opening between said first and second front-side surfaces and exposing at least a portion of each of said first and second front-side surfaces.

17. The method for manufacturing the silicon carbide substrate according to claim 15, wherein the step of covering includes the step of forming a cover on said second main surface.

18. The method for manufacturing the silicon carbide substrate according to claim 15, wherein the step of covering is performed using one or more materials selected from a group consisting of TaC, TiC, WC, VC, ZrC, NbC, MoC, HfC, and TiN.

19. The method for manufacturing the silicon carbide substrate according to claim 15, wherein the step of covering is performed using at least one of a sputtering method and an evaporation method.
